(19) United States
(12) Patent Application Publication
(10) Pub. No.: US 2010/0224953 A1
(43) Pub. Date: Sep. 9, 2010

(54) RECTIFIER APPLICABLE IN HIGH TEMPERATURE CONDITION

(76) Inventors: Charng-Keng Sheen, Yonghe City (TW); Chien-Chih Lu, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/436,115

(22) Filed: May 5, 2009

(30) Foreign Application Priority Data
Mar. 4, 2009 (TW) 98106934

(51) Int. Cl. H01L 29/86

(52) U.S. Cl. 257/494; 257/E29.325

(57) ABSTRACT

A rectifier for high temperature application includes a conductive semiconductor layer, a conductive epitaxial layer, and a plurality of conductive doped regions within the conductive epitaxial layer. A fringe conductive doped region is formed surrounding the conductive doped region, and an outer fringe conductive doped region is formed further surrounding the fringe conductive doped region. A first metal layer is formed on the upper surface of the conductive semiconductor substrate covering the entire conductive doped regions, and contacting at least a portion of the fringe conductive doped region. A second metal layer is formed on the lower surface of the conductive semiconductor substrate.

### BACKGROUND OF THE INVENTION

1. Field of the Invention

The present invention relates to a rectifier applicable for high temperature condition, in particular to a rectifier with high reverse surge capability for high temperature condition.

2. Description of Related Art

With the development of semiconductor technology, diodes are commonly used for power devices. For example, PN junction diode is applied in alternator system for rectification. PN junction diode has property of low reverse leakage current, but high forward voltage (VF). During operation for a PN junction diode, the value of VF is about 1V so that more energy is consumed in the application.

On the other hand, Schottky diode is another type of diode with a much lower VF than the PN junction diode. However, the Schottky diode has a higher reverse leakage current. Accordingly, Schottky diode is not suitable for operation in the high temperature condition.

Therefore, in view of the above mentioned disadvantages, the present invention is provided to overcome the above mentioned problems based on years experience and deliberate research.

### SUMMARY OF THE INVENTION

The primary objective of the present invention is to provide a rectifier applicable in high temperature condition. The rectifier has properties of low forward voltage (VF) and low reverse leakage current (IR) so that the rectifier can be applied in high temperature condition with high efficiency. Furthermore, the rectifier has structures for decreasing the accumulation of electric field so that the rectifier can have high reverse surge capability.

To achieve the above-mentioned objective, a rectifier is provided by the present invention. The rectifier includes a conductive semiconductor layer, a conductive epitaxial layer, a plurality of conductive doped regions, a fringe conductive doped region, at least one outer fringe conductive doped region, a first metal layer, and a second metal layer. The conductive epitaxial layer is formed on the conductive semiconductor layer. The conductive doped regions are formed in the conductive epitaxial layer; the fringe conductive doped region and the outer fringe conductive doped region are formed within the conductive epitaxial layer.

Furthermore, the fringe conductive doped region is formed surrounding the conductive doped area, and the outer fringe conductive doped region is formed surrounding the fringe conductive doped region. The first metal layer is formed on the conductive epitaxial layer and entirely covering the conductive doped region. The first metal layer partially covering the fringe conductive doped region. The second metal layer is formed on the lower surface of the conductive semiconductor layer.

The rectifier has properties of low VF and low IR so that the rectifier can be applied in high temperature condition. Furthermore, the rectifier has structures for decreasing the accumulation of electric field so that the rectifier can survive in a reverse bias condition. Therefore, the diode is protected from failure of high reverse bias.

In order to further understand the techniques, means, and effects that the present invention takes for achieving the prescribed objectives, the following detailed descriptions and appended drawings are hereby referred; such that, through which the purposes, features, and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 illustrates a top view of a first preferred embodiment of a rectifier according to the present invention;

FIG. 2 illustrates a cross-sectional view taken along A-A′ in FIG. 1;

FIG. 3 illustrates a cross-sectional view taken along B-B′ in FIG. 1;

FIG. 4 illustrates a second preferred embodiment of a rectifier according to the present invention;

FIG. 5 illustrates a third preferred embodiment of a rectifier according to the present invention;

FIGS. 6 to 13 illustrate manufacturing steps of a rectifier according to the present invention;

FIG. 14 illustrates a fourth preferred embodiment of a rectifier according to the present invention;

FIG. 15 illustrates a fifth preferred embodiment of a rectifier according to the present invention;

FIG. 16 illustrates a sixth preferred embodiment of a rectifier according to the present invention; and

FIG. 17 illustrates a seventh preferred embodiment of a rectifier according to the present invention.

### DETAILED DESCRIPTION OF THE PREFERRED EMBODIMENTS

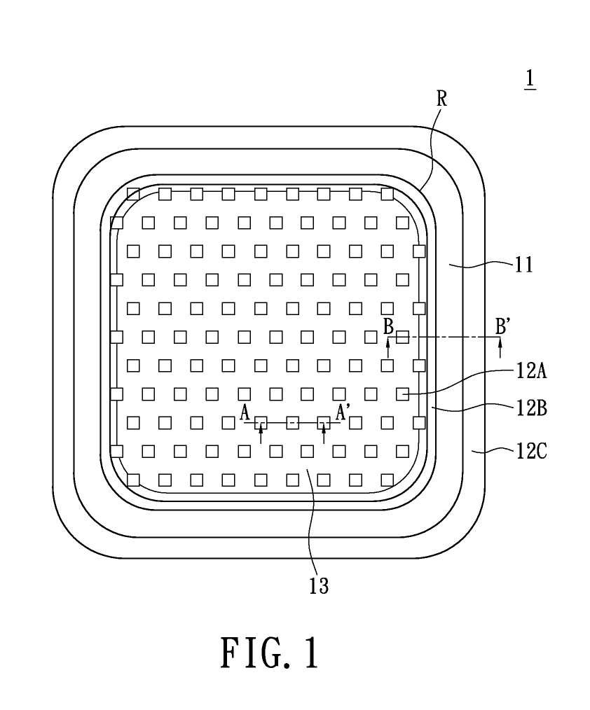

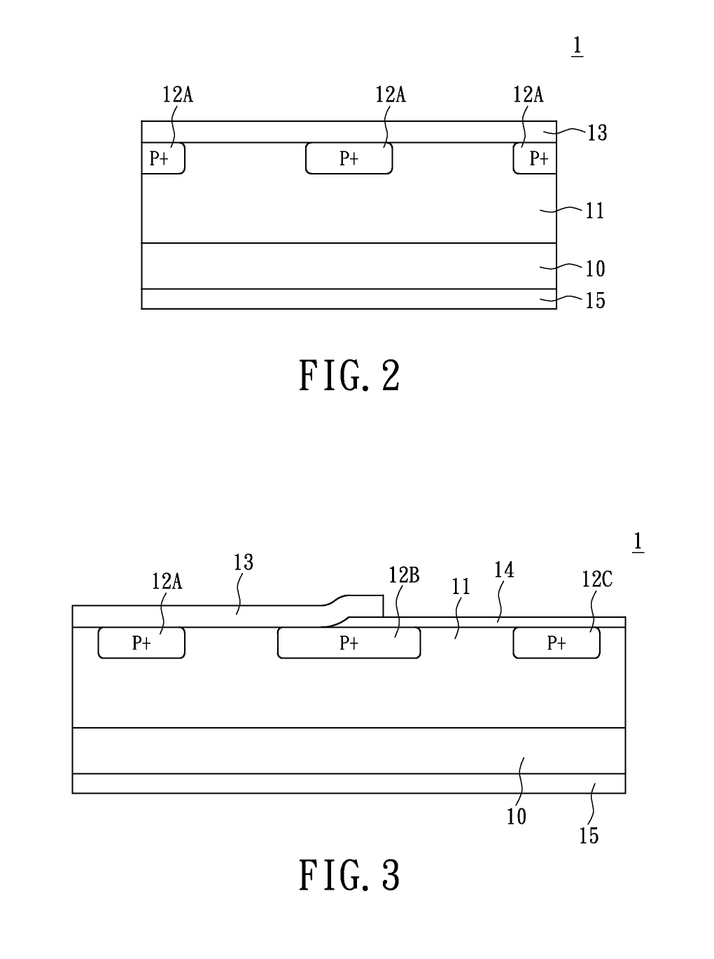

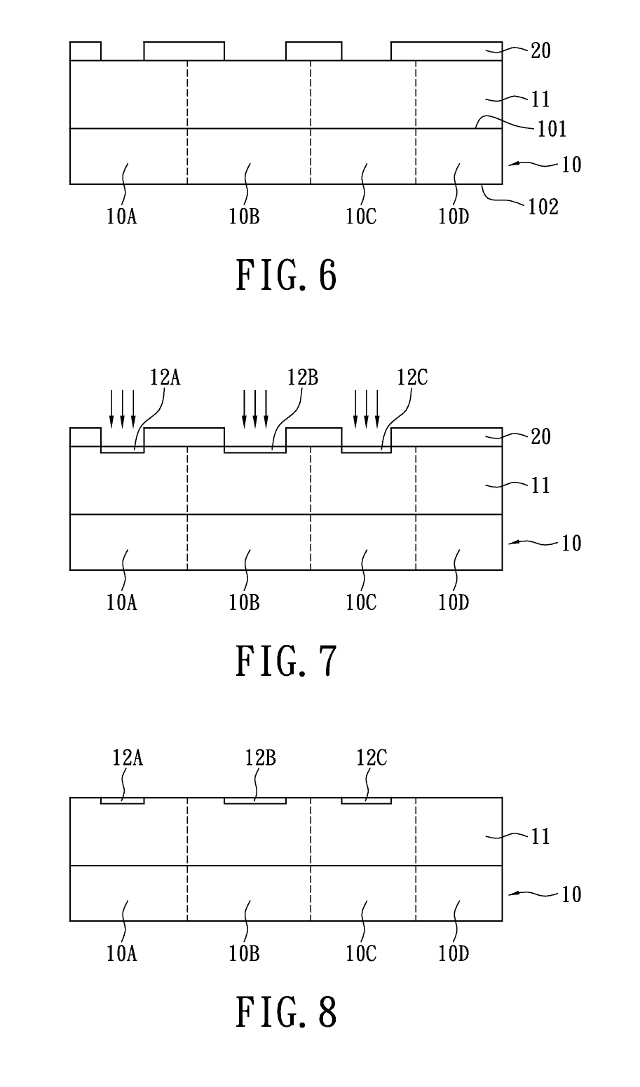

Please refer to FIG. 1, the present invention provides a rectifier 1 which can be used under high temperature application. The rectifier 1 provides high efficiency in high temperature operation and high reliability in high reverse bias condition. The rectifier 1 has a conductive semiconductor layer 10 having an upper surface 101 and a lower surface 102 (as shown in FIG. 6), a conductive epitaxial layer 11, a plurality of conductive doped region 12A, a fringe conductive doped region 12B, at least one outer fringe conductive doped region 12C, a first metal layer 13, and a second metal layer 15 (shown in FIGS. 2 and 3).

FIG. 1 shows a top view of the first preferred embodiment of a rectifier according to the present invention. The conductive semiconductor layer 10 and the conductive epitaxial layer 11 are N-type. The conductive semiconductor layer 10 is referenced as N⁺ and the conductive epitaxial layer 11 is referenced as N in accordance to the doping concentration. On the other hand, all of the conductive doped regions 12A, the fringe conductive doped region 12B, and the outer fringe conductive doped region 12C are P⁺ doped region.

FIG. 2 shows a cross-section view taken along A-A′ of FIG. 1. The conductive epitaxial layer 11 is formed on the upper surface 101 of conductive semiconductor layer 10, and the conductive doped regions 12A are formed in the conductive epitaxial layer 11. In other words, the conductive doped regions 12A are P-doped islands in the conductive epitaxial layer 11. The conductive doped regions 12A can be quadrangle-shaped (for example, rectangle-shaped), circle-shaped, or hexagon-shaped, and they are covered by the first metal layer 13. Therefore, the first metal layer 13 performs as a low schottky barrier so that the rectifier 1 of the present invention has property of low forward voltage (low VF).

On the other hand, the construction of the conductive epitaxial layer 11 and the conductive doped regions 12A performs as a PN junction diode that has low IR leakage in reverse bias. In other words, the rectifier 1 has low current leakage so that the rectifier 1 can be used under high temperature application. Accordingly, the rectifier 1 of the present invention has properties of low forward voltage (VF) and low reverse leakage current.

FIG. 3 shows a cross-section view taken along B-B′ of FIG. 1. Please refer to FIGS. 1, 3, and 4; the fringe conductive doped region 12B and the outer fringe conductive doped region 12C are formed in the conductive epitaxial layer 11. The fringe conductive doped region 12B surrounds the conductive doped region 12A. In other words, the conductive doped regions 12A are disposed within the fringe conductive doped region 12B, and the first metal layer 13 covers a portion of the fringe conductive doped region 12B. The fringe of the first metal layer 13 extends from the area of the conductive doped region 12A to contact with the fringe conductive doped region 12B that surrounds the conductive doped region 12A. The contact portion of the first metal layer 13 and the fringe conductive doped region 12B can be adjusted depending on the manufacturing processes.

With regard to the top view of the rectifier 1, the first metal layer 13 covers at least a portion of the fringe conductive doped region 12B. For example, the first metal layer 13 may cover a portion of the fringe conductive doped region 12B or the entire fringe conductive doped region 12B. Preferably, the first metal layer 13 covers half of the fringe conductive doped region 12B. The electric contact of the first metal layer 13 and fringe conductive doped region 12B can prevent the rectifier 1 from failure that results from high electric field in the fringe of the rectifier 1.

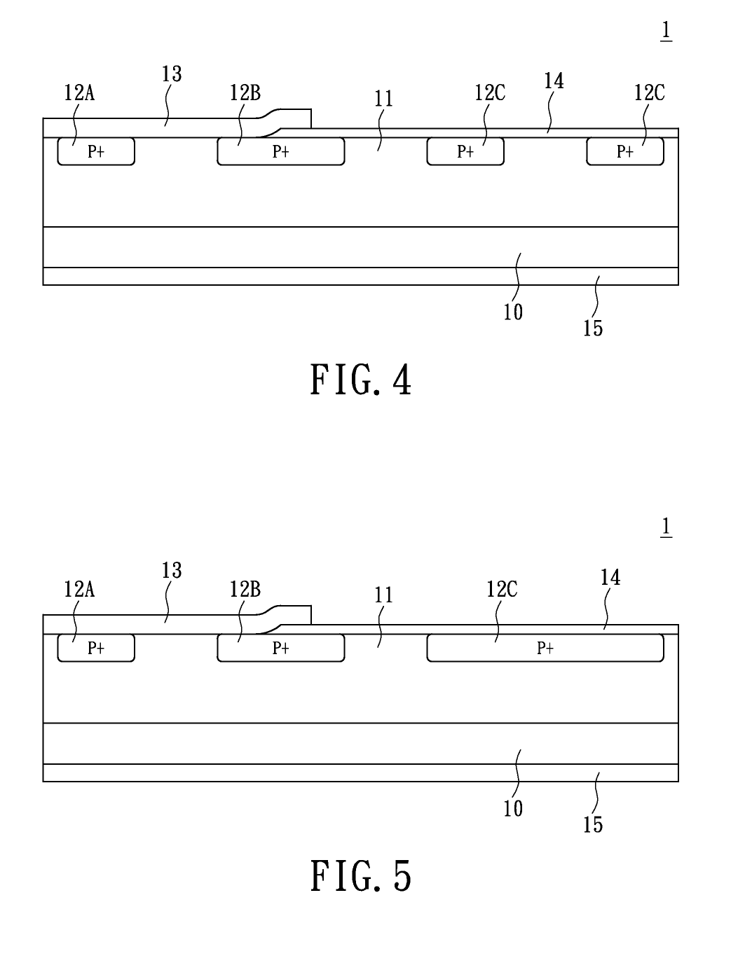

There is only one outer fringe conductive doped region 12C shown in FIG. 3, and the width of the outer fringe conductive doped region 12C is equal to the minimum width in the manufacturing process. FIG. 4 shows two outer fringe conductive doped regions 12C formed in the conductive epitaxial layer 11, and the width of each outer fringe conductive doped region 12C is also equal to the minimum width in the manufacturing process. FIG. 5 shows an outer fringe conductive doped region 12C that is wider, and the width of the outer fringe conductive doped region 12C can be twice larger than the minimum width in the manufacturing process. Accordingly, the amount and the size of the outer fringe conductive doped region 12C can be adjusted for the various applications.

With respect to the shape of the fringe conductive doped region 12B, the structure of the fringe conductive doped region 12B of the present invention can protect the rectifier 1 from failure due to the high electric field. In the present invention, the fringe conductive doped region 12B is substantially quadrangle-shaped and the corners of the quadrangular fringe conductive doped region 12B are not right angles so as to prevent the electric field from accumulating at the corners. For the reason of photo-mask design, the corners of the quadrangular fringe conductive doped region 12B are arc-shaped corners R. On the other hand, the fringe conductive doped region 12B can be hexagon-shaped, and each corner of the fringe conductive doped region 12B can similarly be arc-shaped corners R for preventing the accumulated electric field.

Moreover, the shape of the first metal layer 13 may be formed corresponding to the shape of the fringe conductive doped region 12B. In other words, the first metal layer 13 can be quadrangle-shaped or hexagon-shaped, but regardless of which, the corners of the first metal layer 13 are arc-shaped corners R (i.e., non-right angle). From the top view of the rectifier 1, it can be clearly seen that the corners of the fringe conductive doped region 12B and the first metal layer 13 are arc-shaped corners R.

On the other hand, the outer fringe conductive doped region 12C is formed in the conductive epitaxial layer 11 and surrounds the fringe conductive doped region 12B. The first metal layer 13 does not cover the outer fringe conductive doped region 12C. Please refer to FIG. 3, an isolation layer 14 covers the outer fringe conductive doped region 12C; furthermore, the isolation layer 14 covers a portion of the fringe conductive doped region 12B that is not covered by the first metal layer 13. Therein, the outer fringe conductive doped region 12C as well as the fringe conductive doped region 12B has arc-shaped corners R. The outer fringe conductive doped region 12C provides a smooth electric field so as to protect the rectifier 1 in reverse bias condition. The amount of the outer fringe conductive doped region 12C (shown in FIGS. 3 and 4) and the size of the outer fringe conductive doped region 12C (shown in FIG. 5) can be adjusted for smoothing the electric field.

Accordingly, the above-mentioned structures are provided for protecting the rectifier 1 from the reverse surge in reverse bias condition. In other words, by utilizing the metal layer 13 to contact with a portion of the fringe conductive doped region 12B, and other structures such as the arc-shaped corners and the outer fringe conductive doped region 12C, the protection of the fringe portion of the device during reverse bias condition is thereby achieved.

The conductive epitaxial layer 11 is covered by an isolation layer 14 so that the outer fringe conductive doped region 12C is covered by the isolation layer 14 along with a portion of the fringe conductive doped region 12B that is not covered by the first metal layer 13 (please note that the isolation layer 14 is omitted in FIG. 1). The isolation layer 14 is used for insulating the outer fringe conductive doped region 12C from the packaging material. The lower surface 102 of the conductive semiconductor substrate 10 has a second metal layer 15, which is applied to an electrode.

FIGS. 6 to 13 show the manufacturing procedures of the rectifier 1, and the steps are as follows:

Step (a): Providing a conductive semiconductor layer 10 as shown in FIG. 6. The conductive semiconductor substrate 10 is an N⁺ type substrate, which includes a center region 10A, a fringe region 10B, an outer fringe region 10C, and a strip line 10D.

Step (b): Forming a conductive epitaxial layer 11 on the conductive semiconductor layer 10 as shown in FIG. 6. In the present preferred embodiment, the conductive epitaxial layer 11 is an N-type epitaxial layer.

Step (c): Forming a plurality of conductive doped regions 12A, a fringe conductive doped region 12B, and at least one outer fringe conductive doped region 12C in the conductive epitaxial layer 11 as shown in FIG. 7. Then, the conductive doped region 12A, the fringe conductive doped region 12B, and the outer fringe conductive doped region 12C are respectively defined in the center region 10A, the fringe region 10B, and the outer fringe region 10C (Please note that only one conductive doped region 12A is shown in FIG. 7) by using photoresist 20. The P⁺ dopant is doped into the conductive epitaxial layer 11 by ion implantation.

The outer fringe conductive doped region 12C is formed in the conductive epitaxial layer 11 and surrounds the fringe conductive doped region 12B. The outer fringe conductive doped region 12C as well as the outer fringe conductive doped region 12B has arc-shaped corners R, wherein the arc-shaped corners R may provide a smooth electric field so as to protect the rectifier 1 in reverse bias condition. Moreover, the amount of the outer fringe conductive doped region 12C and the size of the outer fringe conductive doped region 12C can be adjusted for smoothing the electric field so as to protect the rectifier 1.

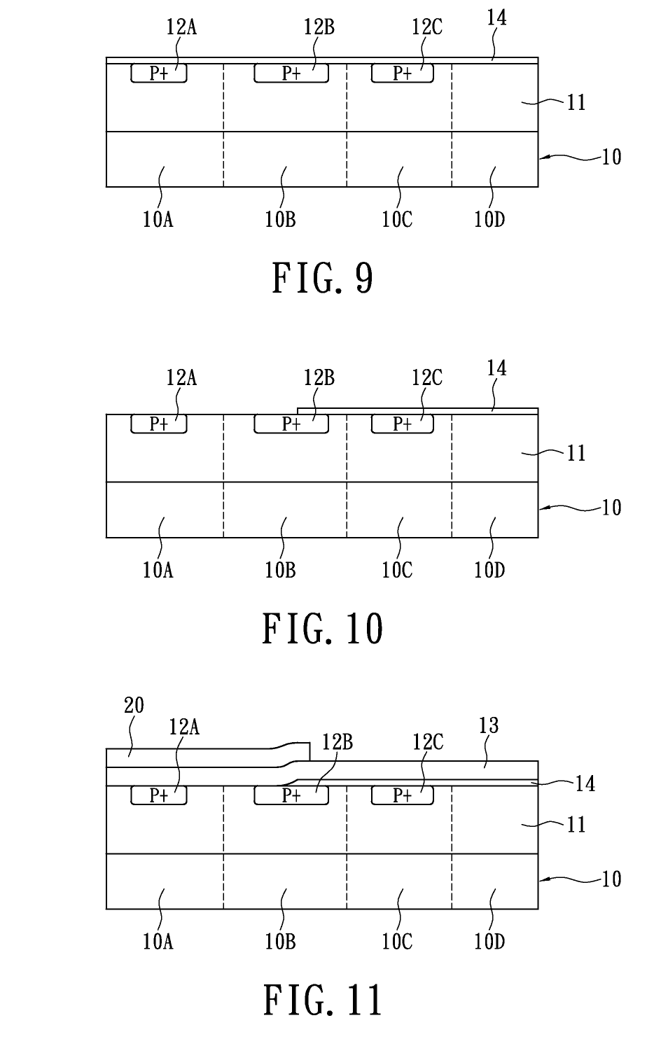

Step (D): Forming an isolation layer 14 on the conductive epitaxial layer 11 as shown in FIGS. 9 and 10. The isolation layer 14 covers the outer fringe conductive doped region 12C and a portion of the fringe conductive doped region 12B (Please note that the exposed portion of the fringe conductive doped region 12B is covering the first metal layer 13). In this step, an oxidization layer (i.e., the isolation layer 14) is formed by an oxidization method, wherein high temperature of the oxidization method is applied for driving the P⁺ dopant into a predetermined depth in the conductive epitaxial layer 11. Thus, the isolation layer 14 is formed on the conductive epitaxial layer 11 and covering the outer fringe conductive doped region 12C and a portion of the fringe conductive doped region 12B.

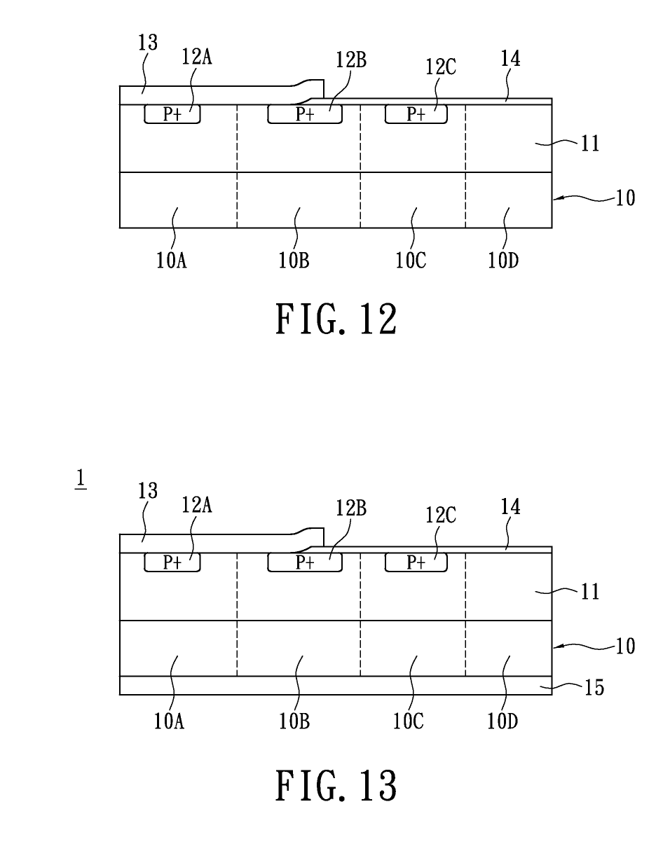

Step (e): Forming a first metal layer 13 as shown in FIGS. 11 and 12. In this step, the first metal layer 13 is formed on the conductive epitaxial layer 11 and the isolation layer 14 by a metallic process. The first metal layer 13 entirely covers the conductive doped region 12A along with a part of the fringe conductive doped region 12B (i.e., the part of the fringe conductive doped region 12B is a part that is not covered by the isolation layer 14, and the portion of the fringe conductive doped region 12B is a portion that is not covered by the first metal layer 13).

In the present preferred embodiment, the fringe of the first metal layer 13 bridges over the isolation layer 14 for preventing the fringe conductive doped region 12B from being exposed. In other words, the first metal layer 13 extends from the area of the conductive doped regions 12A, and contacts the fringe conductive doped region doping area 12B surrounding the conductive doped regions 12A (see FIG. 1). The contact area between the first metal layer 13 and the fringe conductive doped region 12B can be adjusted according to the processes. For example, the first metal layer 13 may cover a portion of the fringe conductive doped region 12B, or the first metal layer 13 may entirely cover the fringe conductive doped region 12B. Preferably, the first metal layer 13 covers half of the fringe conductive doped region 12B.

Step (e): Forming a second metal layer 15 on the lower surface 101 of the conductive semiconductor substrate 10 as shown in FIG. 13. Moreover, a thinning step is further provided for thinning the thickness of the conductive semiconductor layer 10 before the step of forming the second metal layer 15.

Therefore, the rectifier 1 is manufactured by the above-mentioned steps and the rectifier 1 can be used under high temperature application. The rectifier 1 is a diode with low VF and low reverse leakage current, and the diode can survive at a reverse bias condition because of the fringe structure of the rectifier 1.

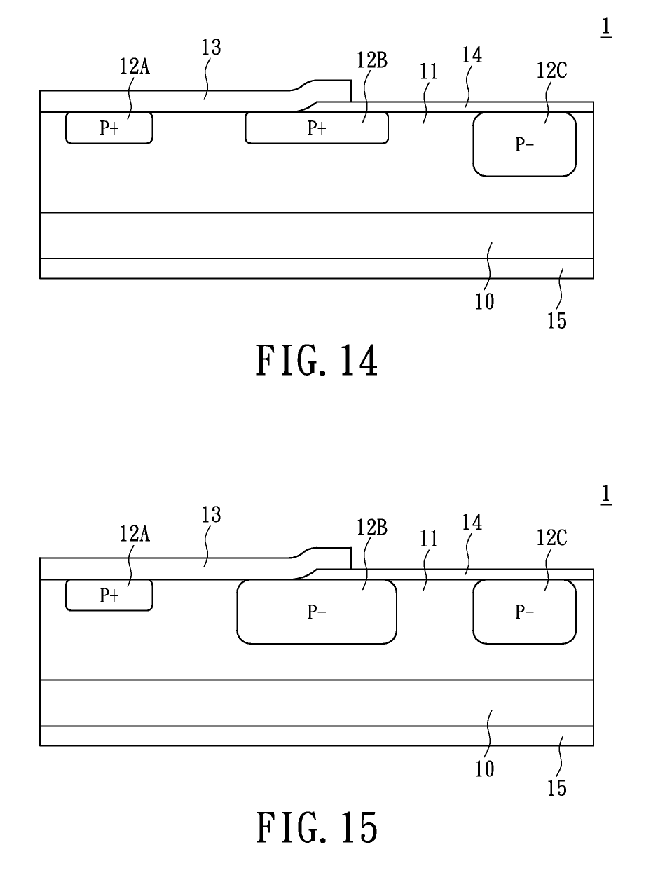

Please refer to FIG. 14; a fourth embodiment of the present invention is shown. The difference between the first and the fourth embodiments is the feature of the fringe conductive doped region 12B and the outer fringe conductive doped region 12C. In the present embodiment, the doping concentration of the outer fringe conductive doped region 12C is less than the fringe conductive doped region 12B and also less than each of the conductive doped region 12A.

Moreover, the doping depth of the outer fringe conductive doped region 12C is greater than the fringe conductive doped region 12B and also greater than each of the conductive doped region 12A. In other words, the conductive doped region 12A and the fringe conductive doped region 12B are P⁺ type with shallow doping depth, and the outer fringe conductive doped region 12C is P⁻ type with deeper doping depth.

Please refer to FIG. 15, a fifth preferred embodiment of the present invention is shown. In the fifth preferred embodiment, the doping concentration of the fringe conductive doped region 12B and the outer fringe conductive doped region 12C are less than the each of the conductive doped region 12A. The doping depth of the fringe conductive doped region 12B and the outer fringe conductive doped region 12C are greater than the each of the conductive doped region 12A. The structure of the fifth preferred embodiment can be manufactured by the following processes. The P⁻ dopant is directly doped in the deeper location in the conductive epitaxial layer 11 so as to form the fringe conductive doped region 12B and the outer fringe conductive doped region 12C by high energy ion-implantation. Then, the P⁺ dopant is doped into the conductive epitaxial layer 11 to form the conductive doped regions 12A, wherein the doping depth of each conductive doped region 12A is less than the fringe conductive doped region 12B and also less than the outer fringe conductive doped region 12C.

On the other hand, the structure of the fifth preferred embodiment can be manufactured by alternative processes. The P⁻ dopant may be doped into the conductive epitaxial layer 11, and then the dopant is driven to the deeper location by high temperature so as to form the fringe conductive doped region 12B and the outer fringe conductive doped region 12C. Next step is doping the P+ dopant into the conductive epitaxial layer 11 to form the conductive doped region 12A, wherein the doping depth of each conductive doped region 12A is less than the fringe conductive doped region 12B and also less than the outer fringe conductive doped region 12C.

Briefly, two photo-masks are used for manufacturing the conductive doped region 12A, the fringe conductive doped region 12B, and the outer fringe conductive doped region 12C with different doping concentration and doping depth. Therein, the remaining steps are referenced to the first preferred embodiment.

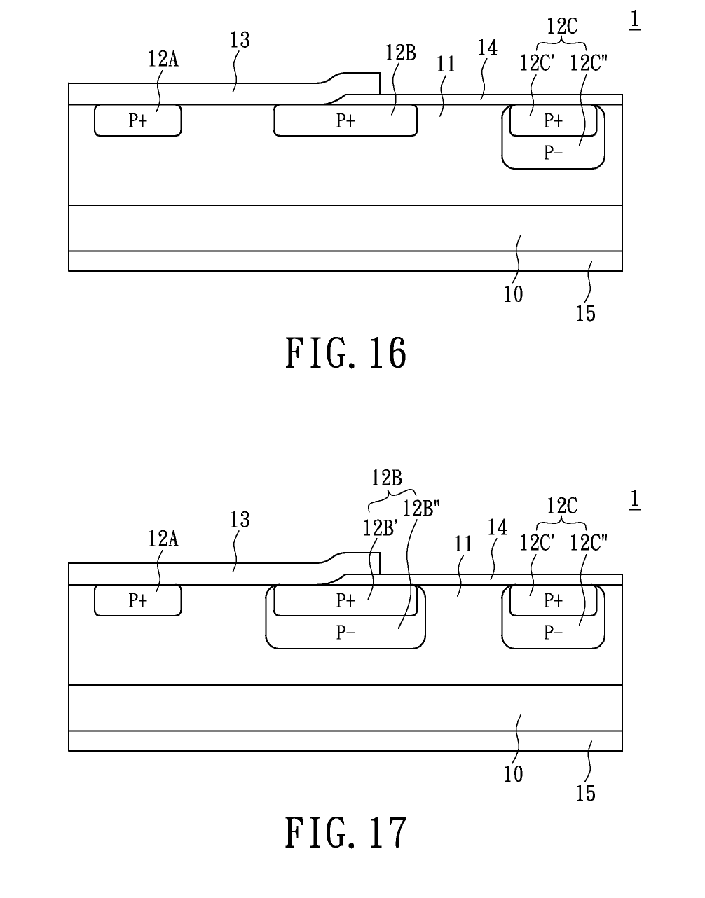

Please refer to FIG. 16, a sixth preferred embodiment of the present invention is shown. The different feature of the fringe conductive doped region 12B and the outer fringe conductive doped region 12C are presented. The conductive doped region 12A and the fringe conductive doped region 12B are P⁺ type. The outer fringe conductive doped region 12C includes an outer fringe conductive heavily doped region 12C′ and an outer fringe conductive slightly doped region 12C″ surrounding the outer fringe conductive heavily doped region 12C′.

Please refer to FIG. 17, a seventh preferred embodiment is shown. The fringe conductive doped region 12B includes a fringe conductive heavily doped region 12B′ and a fringe conductive slightly doped region 12B″ surrounding the fringe conductive heavily doped region 12B′. Similarly, the outer fringe conductive doped region 12C includes an outer fringe conductive heavily doped region 12C′ and an outer fringe conductive slightly doped region 12C″ surrounding the outer fringe conductive heavily doped region 12C′.

Regarding the seventh preferred embodiment, the structure of the embodiment is manufactured by the following methods. The P⁻ dopant is doped into the deeper location of the conductive epitaxial layer 11 by the high energy ion-implantation so as to form the fringe conductive slightly doped region 12B″ and the outer fringe conductive slightly doped region 12C″. Then the P+ dopant is doped into the conductive epitaxial layer 11 so as to form the conductive doped regions 12A, the fringe conductive heavily doped region 12B′, and the outer fringe conductive heavily doped region 12C′.

In addition, the fringe conductive heavily doped region 12B′ is formed in the fringe conductive slightly doped region 12B″; and the outer fringe conductive heavily doped region 12C′ is formed in the outer fringe conductive slightly doped region 12C″. The fringe conductive heavily doped region 12B′ is formed in the fringe conductive slightly doped region 12B″, which together forms the fringe conductive doped region 12B. The outer fringe conductive heavily doped region 12C′ is formed in the outer fringe conductive slightly doped region 12C″, which together forms the outer fringe conductive doped region 12C.

On the other hand, the structure of the seventh preferred embodiment can be manufactured by alternative processes. The P⁻ dopant is doped into the conductive epitaxial layer 11 and then the dopant is driven to the deeper location by high temperature so as to form the fringe conductive slightly doped region 12B″ and the outer fringe conductive slightly doped region 12C″.

Next step is doping the P⁺ dopant into the conductive epitaxial layer 11 so as to form the conductive doped region 12A, the fringe conductive heavily doped region 12B′, and the outer fringe conductive heavily doped region 12C′. The fringe conductive heavily doped region 12B′ is formed in the fringe conductive slightly doped region 12B″, which together forms the fringe conductive doped region 12B. The outer fringe conductive heavily doped region 12C′ is formed in the outer fringe conductive slightly doped region 12C″, which together forms the outer fringe conductive doped region 12C.

Briefly, two photo-masks are used for manufacturing the fringe conductive doped region 12B and the outer fringe conductive doped region 12C. The fringe conductive doped region 12B and the outer fringe conductive doped region 12C can have high-concentration (heavily doped) and low-concentration (slightly doped) regions so that the diode has high reverse surge capability. Therein, the remaining steps are referenced to the first preferred embodiment.

In summary, the present invention has the following advantages. The rectifier 1 applicable to high temperature condition provides high efficiency resulted from the property of low VF. The value of low forward voltage is 0.25 to 0.7 V for a forward current of 100 A. Furthermore, the value of IR is less than 100 nA (the smallest value is 40 nA) measured at room temperature, so that the rectifier 1 can be applied in high temperature environment, such as condition of above 125° C. (i.e., 125 to 225° C.). Therefore, the rectifier 1 can be applied in power supply system of automobiles, such as the alternator system. Moreover, the fringe conductive doped region 12B and the outer fringe conductive doped region 12C are used for increasing the high reverse surge capability of the rectifier 1.

The above-mentioned descriptions represent merely the preferred embodiments of the present invention, without any intention to limit the scope of the present invention thereto. Various equivalent changes, alternations, or modifications based on the claims of present invention are all consequently viewed as being embraced by the scope of the present invention.

What is claimed is:

1. A rectifier applicable in high temperature condition, comprising:
a conductive semiconductor layer having an upper surface and a lower surface that is opposite to the upper surface formed thereon;
a conductive epitaxial layer provided on the upper surface of the conductive semiconductor layer;
a plurality of conductive doped regions formed in the conductive epitaxial layer;
a fringe conductive doped region formed in the conductive epitaxial layer, and surrounding the conductive doped regions;
at least one outer fringe conductive doped region formed in the conductive epitaxial layer, and surrounding the fringe conductive doped region;
a first metal layer formed on the conductive epitaxial layer and provided over an entire surface of the conductive doped region and, and the first metal layer covered on a part of the fringe conductive doped region; and
a second metal layer formed on the lower surface of the conductive semiconductor layer.

2. The rectifier as claimed in claim 1, wherein a width of the outer fringe conductive doped region is twice larger than a minimum width in the manufacturing process.

3. The rectifier as claimed in claim 1, wherein the fringe conductive doped region and the outer fringe conductive doped region each has a doping concentration lower than each of the conductive doped regions; and the fringe conductive doped region and the outer fringe conductive doped region each has a doping depth greater than each of the conductive doped regions.

4. The rectifier as claimed in claim 1, wherein a doping concentration of the outer fringe conductive doped region is lower than the fringe conductive doped region and lower than each of the conductive doped regions; and a doping depth of the outer fringe conductive doped region is greater than the fringe conductive doped region and greater than each of the conductive doped regions.

5. The rectifier as claimed in claim 1, wherein the fringe conductive doped region includes a fringe conductive heavily doped region surrounded by a fringe conductive slightly doped region; and the outer fringe conductive doped region further includes an outer fringe conductive heavily doped region surrounded by an outer fringe conductive slightly doped region.

6. The rectifier as claimed in claim 1, wherein the outer fringe conductive doped region has an outer fringe conductive heavily doped region and an outer fringe conductive slightly doped region surrounding the outer fringe conductive heavily doped region.

7. The rectifier as claimed in claim 1, wherein the first metal layer entirely covers the fringe conductive doped region.

8. The rectifier as claimed in claim 1, wherein the first metal layer covers half of the fringe conductive doped region.

9. The rectifier as claimed in claim 1 further comprises an isolation layer disposed on the conductive epitaxial layer, and the isolation layer covers the outer fringe conductive doped region and a portion of the fringe conductive doped region that is not covered by the first metal layer.
